(19) United States
(12) Patent Application Publication
(10) Pub. No.: US 2008/0045029 A1
(43) Pub. Date: Feb. 21, 2008

(54) Semiconductor substrate processing apparatus

(76) Inventors: Steven Verhaverbeke, San Francisco, CA (US); Brian J. Brown, Palo Alto, CA (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/975,578

(22) Filed: Oct. 19, 2007

Related U.S. Application Data
(62) Division of application No. 10/918,757, filed on Aug. 12, 2004, now abandoned.

(51) Int. Cl. B08B 3/00; H01L 21/461

(52) U.S. Cl. 438/710; 134/26; 257/E21.483

(57) ABSTRACT

According to one aspect of the invention, a semiconductor substrate processing apparatus and a method for processing semiconductor substrates are provided. The semiconductor substrate processing apparatus may include a semiconductor substrate support, a dispense head positioned over the semiconductor substrate support, a liquid container, and a transport subsystem. A semiconductor substrate may be placed on the semiconductor substrate support while a first semiconductor processing liquid is dispensed thereon. The wafer may also be spun by the semiconductor substrate support to remove the first semiconductor processing liquid. The transport subsystem may transport the semiconductor substrate to the liquid container where the semiconductor substrate may be immersed in a second semiconductor processing liquid. The semiconductor substrate may then be removed from the second semiconductor processing liquid while vapor is directed at a surface of the semiconductor substrate where the semiconductor substrate contacts a surface of the second semiconductor processing liquid.

### CROSS-REFERENCE TO RELATED APPLICATIONS

The present application is a Divisional of U.S. Ser. No. 10/918,757, filed Aug. 12, 2004.

### BACKGROUND OF THE INVENTION

1). Field of the Invention

This invention relates to semiconductor substrate processing apparatus and a method for processing semiconductor substrates.

2). Discussion of Related Art

Integrated circuits are formed on semiconductor substrates such as wafers. The formation of the integrated circuits may include numerous processing steps such as deposition of various layers, etching some of the layers, and multiple bakes. The integrated circuits are then separated into individual microelectronic dice, which are packaged and attached to circuit boards.

During the various processing steps involved in the creation of the integrated circuits, various surfaces are formed on the surface of the wafer where the integrated circuits are being formed. Some of these surfaces may be hydrophilic and some of the surfaces may be hydrophobic. Hydrophilic surfaces, such as silicon oxide and silicon nitride, have an affinity for, and do not easily repel, water. While hydrophobic surfaces, such as silicon and low capacitance dielectrics, lack an affinity for water and very easily repel water.

There are two common methods used for cleaning and drying wafers with hydrophilic and hydrophobic surfaces. One method, simply referred to as spin cleaning, involves dispensing a cleaning solution onto the wafer and spinning the wafer to remove the solution, and thus, dry the wafer. The other method, sometimes referred to as immersion cleaning, involves completely immersing the wafer in a cleaning solution, immersing the wafer in de-ionized water, and then removing the wafer from the water while directing isopropyl alcohol vapor onto the wafer where it is contacting the upper surface of the water. This drying process is referred to as Marangoni drying.

Typically, integrated circuit manufacturers use only one of the two types of cleanings in their wafer processing in order to simplify the wafer processing machines and expedite the manufacturing of the integrated circuits. However, such processing is not completely efficient, as spin cleaning does not effectively clean hydrophobic surfaces and the immersion cleaning is generally not preferred for cleaning hydrophilic surfaces.

### SUMMARY OF THE INVENTION

According to one aspect of the invention, a semiconductor substrate processing apparatus and a method for processing semiconductor substrates are provided. The semiconductor substrate processing apparatus may include a semiconductor substrate support, a dispense head positioned over the semiconductor substrate support, a liquid container, and a transport subsystem. A semiconductor substrate may be placed on the semiconductor substrate support while a first semiconductor processing liquid is dispensed thereon. The wafer may also be spun by the semiconductor substrate support to remove the first semiconductor processing liquid. The transport subsystem may transport the semiconductor substrate to the liquid container where the semiconductor substrate may be immersed in a second semiconductor processing liquid. The semiconductor substrate may then be removed from the second semiconductor processing liquid while vapor is directed at a surface of the semiconductor substrate where the semiconductor substrate contacts a surface of the second semiconductor processing liquid.

### BRIEF DESCRIPTION OF THE DRAWINGS

The invention is described by way of example with reference to the accompanying drawings, wherein:

FIG. 1 is a top plan view of a semiconductor substrate processing apparatus, including a plasma ash chamber, a spin clean chamber, and a vertical immersion clean chamber;

FIG. 2 is a cross-sectional side view of the plasma ash processing chamber;

FIG. 3 is a cross-sectional side view of the spin clean processing chamber;

FIG. 4A is a perspective view of a vertical immersion cleaning apparatus within the vertical immersion clean chamber;

FIG. 4B is a cross-sectional side view of the vertical immersion cleaning apparatus of FIG. 4A;

FIG. 5A is a cross-sectional side view of the plasma ash processing chamber illustrating a plasma ash process;

FIG. 5B is a cross-sectional side view of the spin clean processing chamber illustrating a spin cleaning process;

FIGS. 5C-5H are cross-sectional side views of the vertical immersion cleaning apparatus illustrating a vertical immersion cleaning process; and

FIGS. 6A-6E are cross-sectional side views of a semiconductor wafer as the wafer undergoes the processes illustrated in FIGS. 5A-5H.

### DETAILED DESCRIPTION OF THE INVENTION

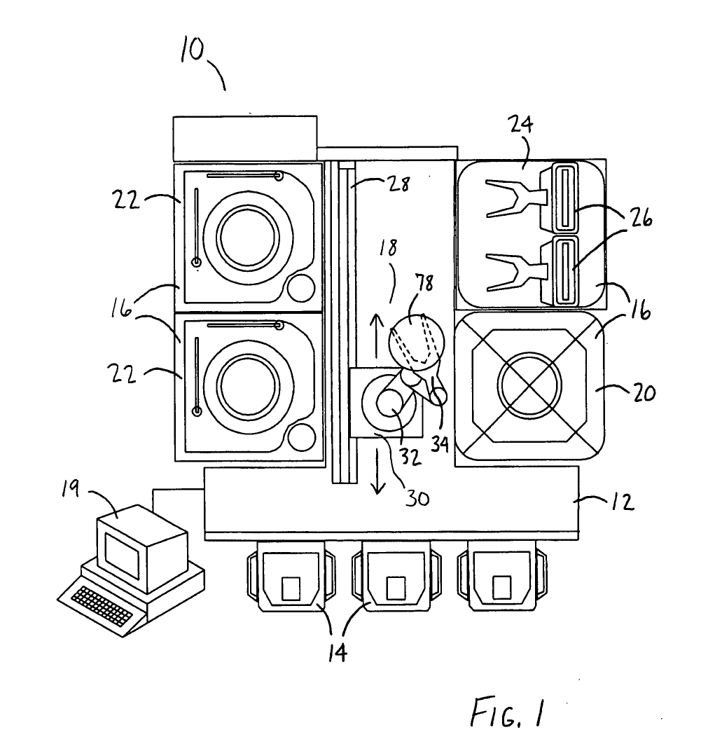

FIG. 1 to FIG. 6E illustrate a semiconductor substrate processing apparatus and a method for processing semiconductor substrates. The semiconductor substrate processing apparatus may include a semiconductor substrate support, a dispense head positioned over the semiconductor substrate support, a liquid container, and a transport subsystem. A semiconductor substrate may be placed on the semiconductor substrate support while a first semiconductor processing liquid is dispensed thereon. The wafer may also be spun by the semiconductor substrate support to remove the first semiconductor processing liquid. The transport subsystem may transport the semiconductor substrate to the liquid container where the semiconductor substrate may be immersed in a second semiconductor processing liquid. The semiconductor substrate may then be removed from the second semiconductor processing liquid while vapor is directed at a surface of the semiconductor substrate where the semiconductor substrate contacts a surface of the second semiconductor processing liquid.

FIG. 1 illustrates an embodiment of a semiconductor wafer processing apparatus 10. The wafer processing apparatus 10 may include a frame 12, wafer cassettes 14, wafer processing chambers 16, a transport subsystem 18, and a computer control console 19. The frame 12 may be substantially square with the cassettes 14 attached at a first end thereof. The transport subsystem 18 may lie at a central portion of the frame 12, and the wafer processing chambers 16 may be arranged on opposing sides of the transport subsystem 18.

The wafer cassettes 14 lie at one end of the frame 12 and may be Front Opening Unified Pods (FOUPs), as is commonly understood in the art. The cassettes 14 may be sized and shaped to hold a plurality of semiconductor substrates, such as wafers, with diameters of, for example, 200 or 300 millimeters.

The wafer processing chambers 16 may include first, second, and third types of processing chambers, such as a plasma ash chamber 20, spin clean chambers 22, and a vertical immersion clean chamber 24. The vertical immersion clean chamber 24 may include vertical immersion clean apparatuses 26.

The transport subsystem 18, or mechanism, may include a robot track 28 and a robot 30. The robot track 28 may lie on the frame 12 and extend from the first end of the frame 12, near the wafer cassettes 14, to a second end of the frame 12 which opposes the wafer cassettes 14. The robot 30 may be moveably attached to the robot track 28 and may include a robot arm 32 and a wafer support 34.

It should be noted that the terms wafer support, wafer chuck, and wafer gripper may be used interchangeably and that use of any particular one of these terms is not meant to be limiting in any way.

The wafer support 34 may be able to support semiconductor substrates, such as wafers with diameters of, for example, 200 or 300 mm. The robot arm 32 may be moveable relative to the robot 30 to extend the wafer support 34 into any one of the wafer cassettes 14 or the wafer processing chambers 16, depending on the position of the robot 30 on the robot track 28.

The computer control console 19 may be in the form of the computer having memory for storing a set of instructions in a processor connected to the memory for executing the instructions, as is commonly understood in the art. The computer control console 19 may be electrically connected to the frame 12, the cassettes 14, the wafer processing chambers 16, and the transport subsystem 18.

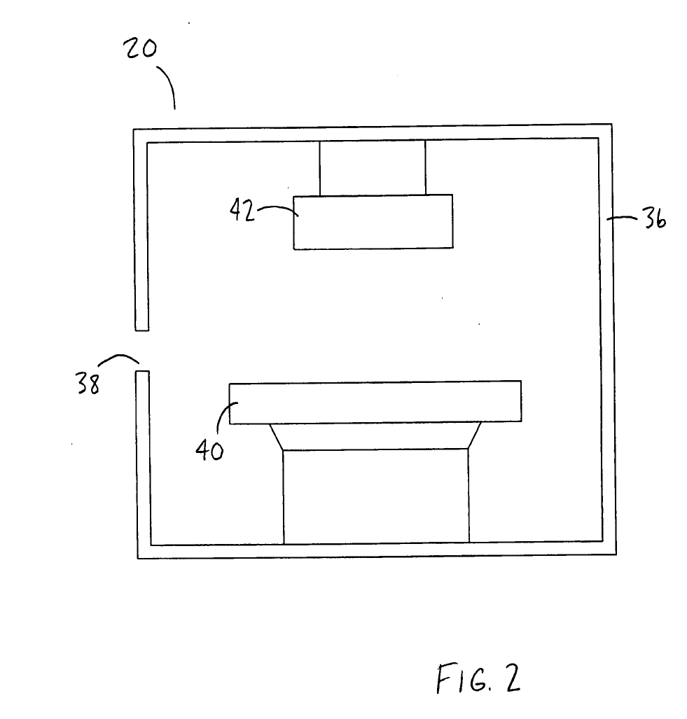

FIG. 2 illustrates the plasma ash processing chamber 20. The plasma ash chamber 20 may include a chamber wall 36, with a wafer slit 38 therein, a wafer chuck 40, and a plasma generator 42. The chamber wall 36 may be, in cross-section, substantially square, and the wafer slit 38 may lie on a side of the chamber wall 36 which is closest to the transport subsystem 18. The wafer chuck 40 may be attached to a lower portion of the chamber wall 36 and may be sized appropriately to support, for example, semiconductor wafers with diameters of 200 or 300 mm. The plasma generator 42 may be attached to an upper end of the chamber wall 36 and, although not illustrated, may include a high voltage electrode and be connected to a plasma gas source, as is commonly understood in the art.

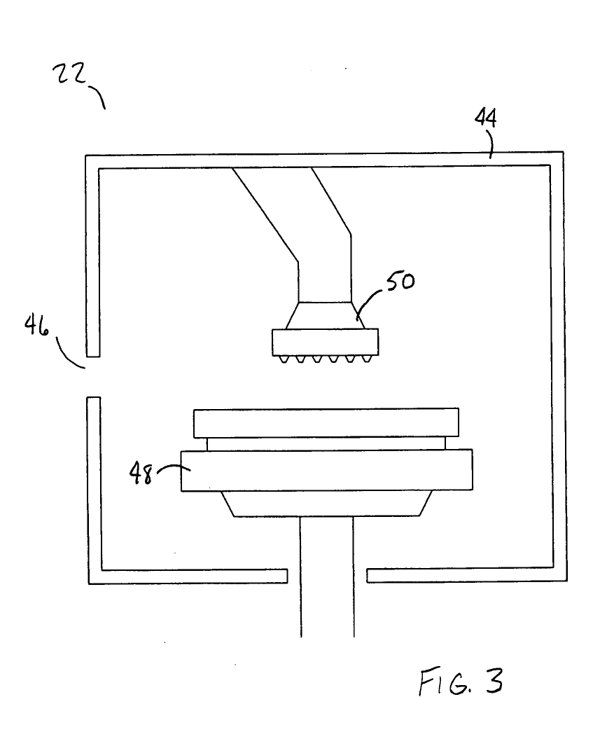

FIG. 3 illustrates one of the spin clean chambers 22. The spin clean chamber 22 may include a chamber wall 44 with a wafer slit 46 therein, a wafer chuck 48, and a dispense head 50. The chamber wall 44 may be, in cross-section, substantially square with the wafer slit 46 on a side of the chamber wall 44 closest to the transport subsystem 18. The wafer chuck 48 may have a similar size to the wafer chuck 40 illustrated in FIG. 2, and may lie at a lower portion of the spin clean chamber 22. Although not illustrated in detail, the wafer chuck 48 may be attached to the frame 12 such that it is capable of rotating, or spinning, a semiconductor wafer at a high rate, such as 3000 revolutions per minute (rpm). The dispense head 50 may be suspended from an upper portion of the chamber wall 44 and lie directly over a central portion of the wafer chuck 48. The dispense head 50, although not illustrated in detail, may be connected to a semiconductor processing fluid source, as is commonly understood in the art.

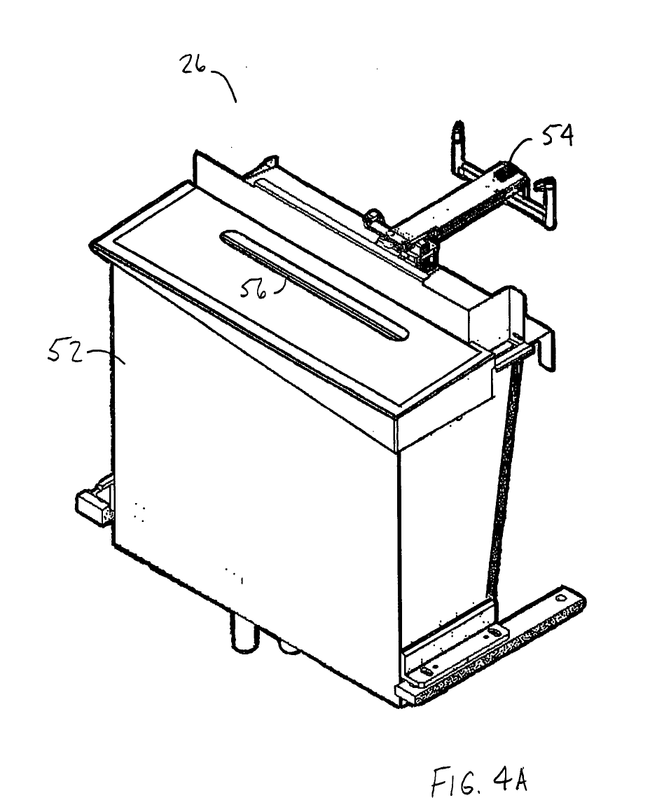

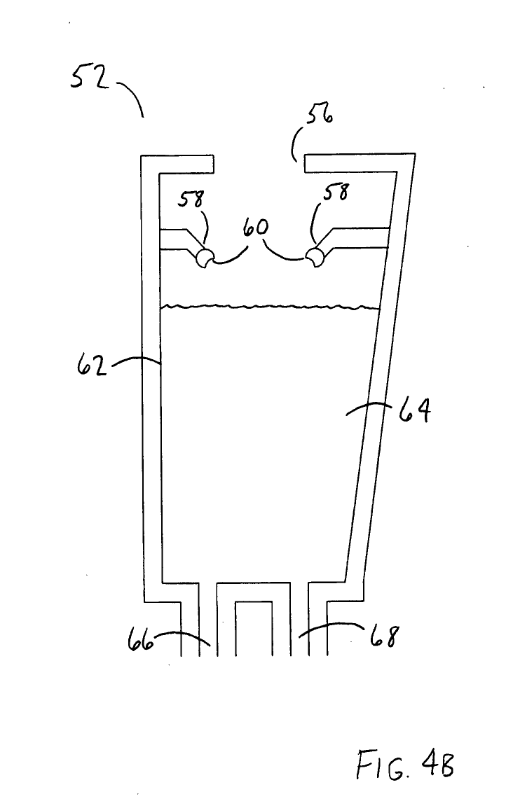

FIG. 4A illustrates one of the vertical immersion clean apparatuses 26. The vertical immersion clean apparatus 26 may include a main body 52 and a wafer gripper 54. The main body 52 may be substantially rectangular in shape with a wafer slit 56 at an upper end thereof. The wafer gripper 54 may be moveably attached to the main body 52 and sized to receive a semiconductor substrate, such as a semiconductor wafer with a diameter of 200 or 300 mm. It should be noted that the wafer gripper 54 may be understood to be a component of the transport subsystem 18.

FIG. 4B illustrates the main body 52 of one of the vertical immersion clean apparatuses 26. In addition to the wafer slit 56, the main body 52 includes vapor pipes 58, with vapor nozzles 60, a liquid tank 62, which may include a first tank liquid 64 therein, an inlet 66, and a drain 68. The vapor pipes 58 may be attached to walls of the main body 52 on opposing sides of the wafer slit 56. The vapor pipes 58 may include openings therein which form the vapor nozzles 60. Although not illustrated, it should be understood that the vapor pipes 58 may be connected to a semiconductor processing vapor source. The liquid tank 62 may occupy the remainder of the main body 52 below the vapor pipes 58. The inlet 66 and the drain 68 may lie at a lower end of the main body and be connected to the liquid tank 62. The first tank liquid 64 may be pumped into the liquid tank 62 through the inlet 66.

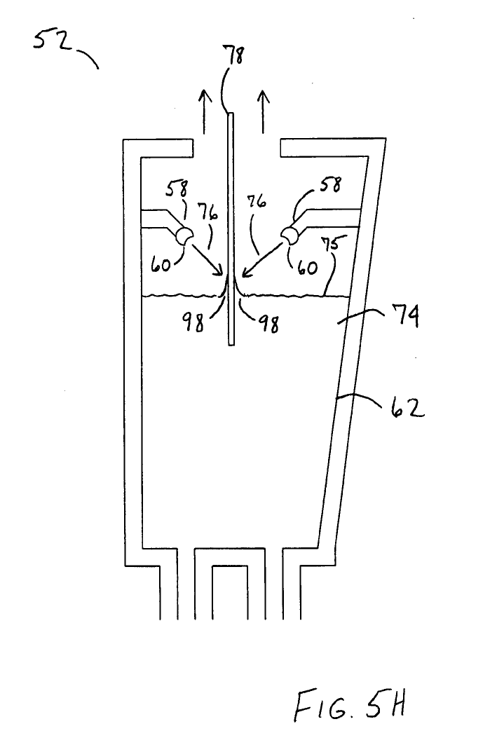

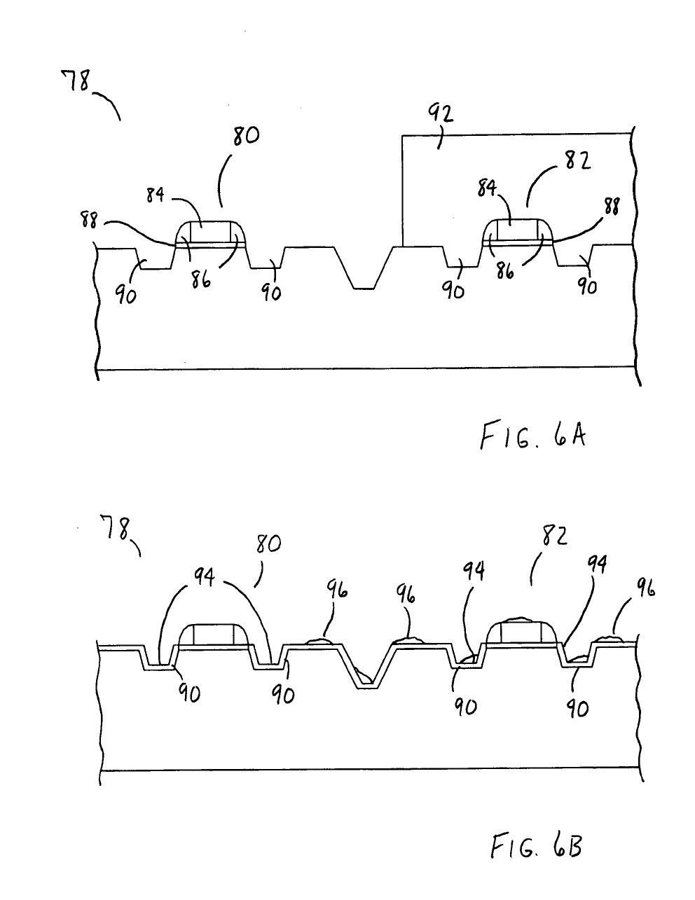

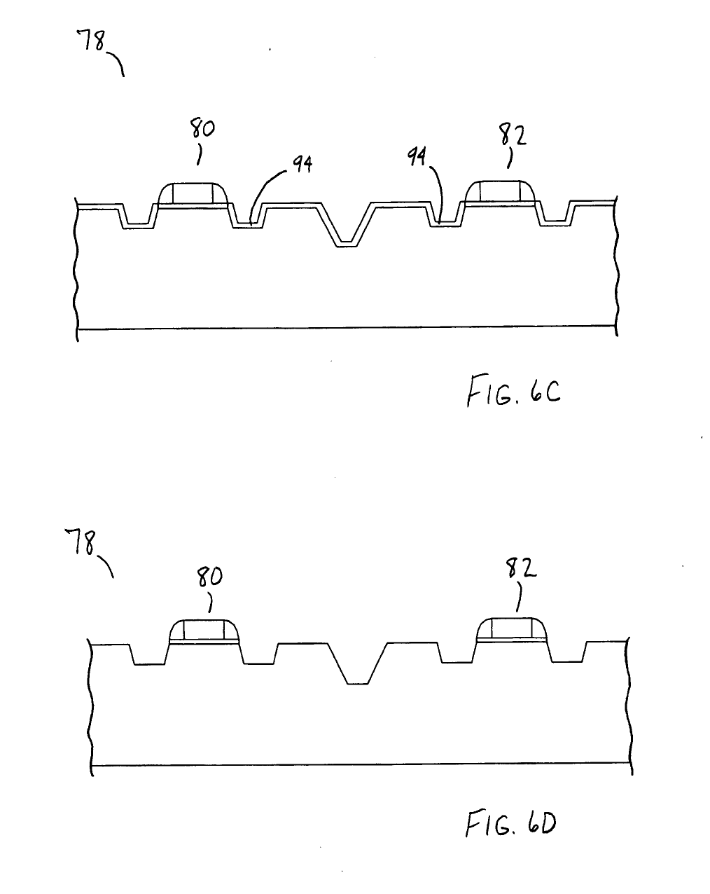

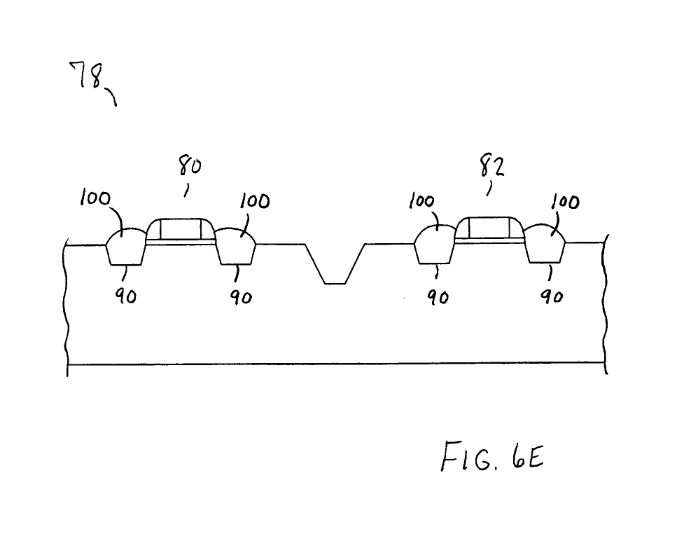

In use, referring again to FIG. 1, a plurality of semiconductor substrates, such as wafers 78, may be inserted into the wafer cassettes 14. FIG. 6A illustrates a portion of an example of one of the semiconductor wafers 78. The wafer 78 may be made of silicon and have a p-type transistor 80 and an n-type transistor 82 formed on an upper surface thereof, with a trench in between. Each of the transistors 80 and 82 may include a gate 84, spacers 86 formed on opposing sides of the gate 84, a gate dielectric 88 beneath the gate, and source and drain trenches 90. A photoresist layer 92 has been formed on the wafer 78, however, the photoresist layer 92 may only cover the n-type transistor 82 in order to protect the n-type transistor 82 from a wafer manufacturing process, such as ion implantation, which may be performed on the p-type transistor 80.

Referring again to FIG. 1, the computer control console 19 may control the transport subsystem 18 and the wafer processing chambers 16 to perform the following processing steps. The robot 30 may be moved along the robot track 28 into a position near the wafer cassettes 14. The robot arm 32 may reach the wafer support 34 into one of the wafer cassettes 14 and retrieve one of the semiconductor wafers 78 from one of the wafer cassettes 14. The robot 30 may then transport the wafer 78 into the plasma ash chamber 20.

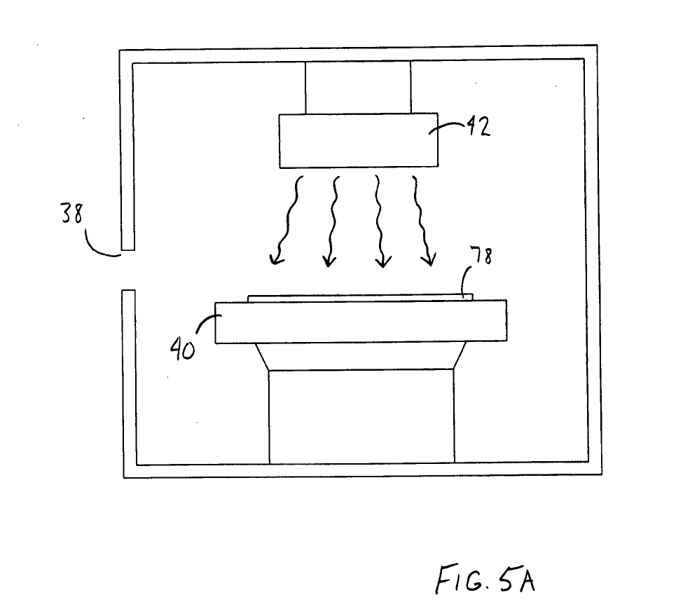

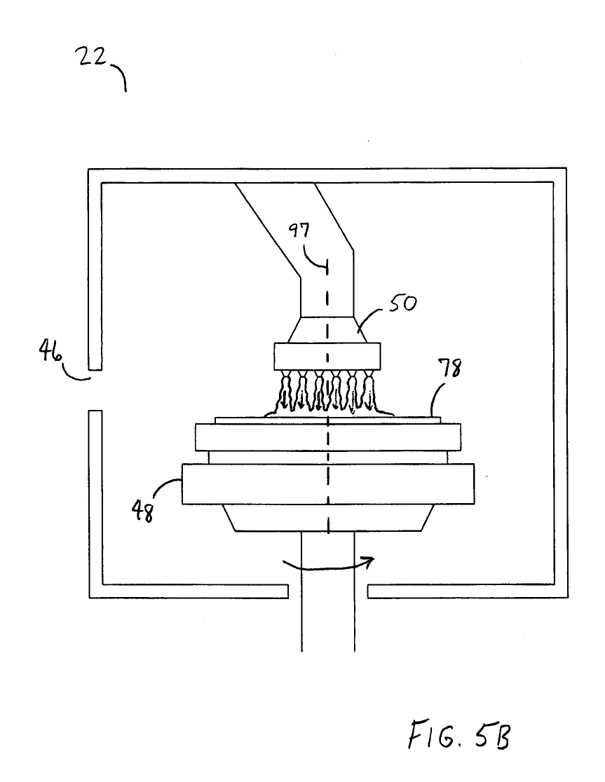

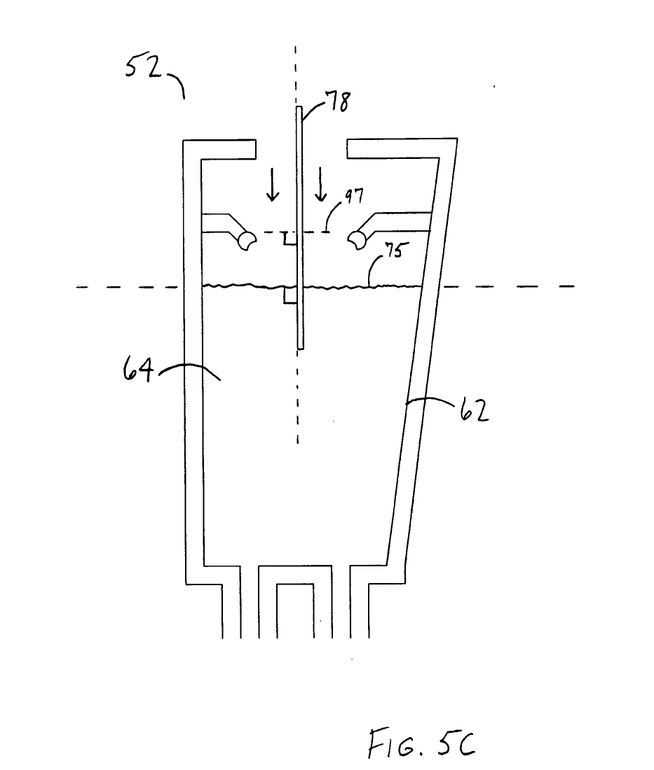

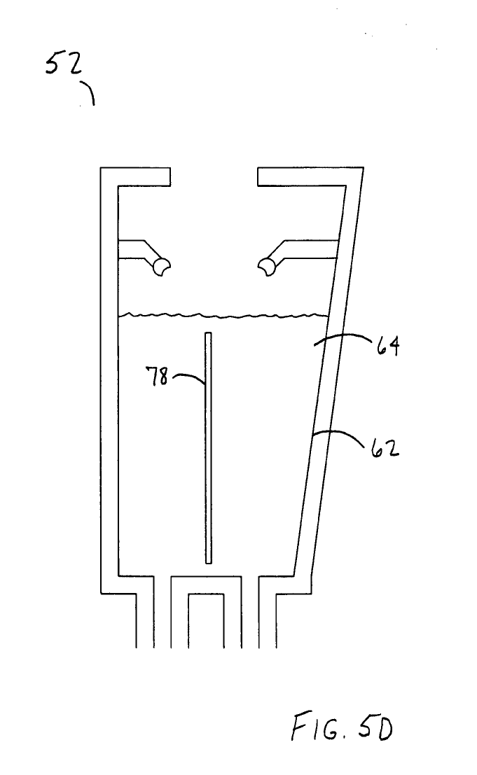

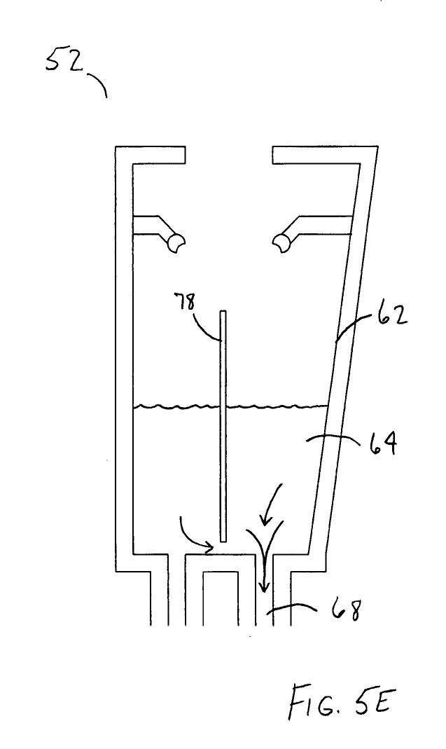

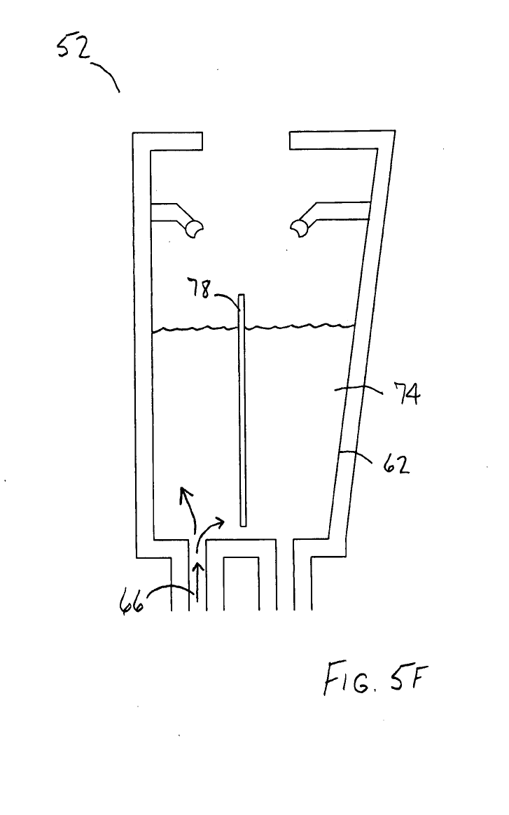

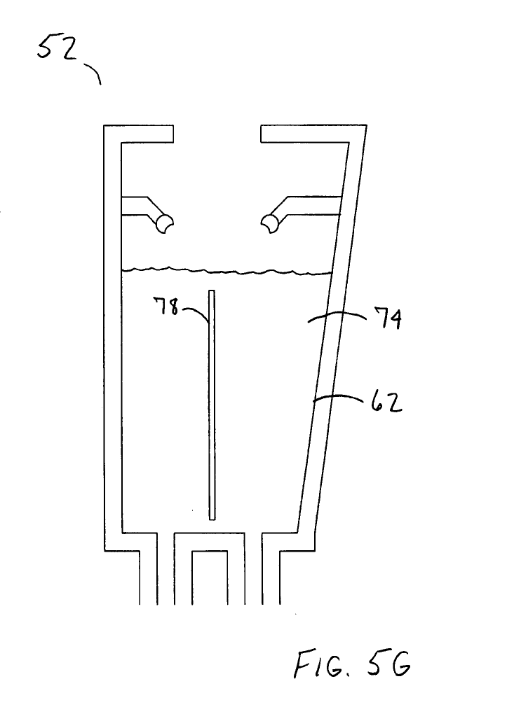

Referring to FIG. 5A, the robot may reach the wafer support 34 into the plasma ash chamber 20, through the wafer slit 38, and place the wafer 78 on the wafer chuck 40. The plasma generator 42 may then be activated to create a high-energy plasma from a particular processing gas, such as oxygen. The plasma 70 may be directed onto the upper surface of the wafer 78 having the transistors 80 and 82 formed thereon.

Referring now to FIG. 6B, after the wafer 78 has undergone the plasma treatment within the plasma ash chamber 20, the photoresist layer 92 has been substantially completely removed. However, an oxide layer 94 has grown on the upper surface of the substrate 78, particularly within the source and drain trenches 90. The oxide layer 94 may be intentionally grown in an oxidation furnace. The oxide layer 94 may have a hydrophilic surface. The plasma ash process may also leave behind other debris or residue such as ash from the removed photoresist or metal particles 96.

Referring again to FIG. 1, the robot 30 may then utilize the robot arm 32 to remove the wafer 78 from the plasma ash chamber 20 and transport the wafer 78 into one of the spin clean chambers 22.

Referring to FIG. 5B, the robot arm 32 may place the wafer 78 on the wafer chuck 48 within the spin clean chamber 22 to remove the photoresist or metal particles from and clean the wafer 78. Within the spin clean chamber 22, a semiconductor processing liquid, such as ammonia and hydrogen peroxide, may be dispensed onto the wafer 78 through the dispense head 50. The wafer 78 may then be spun by the wafer chuck 48, such as at 1000 rpm, about a central axis 97 of the wafer 78. A centrifugal force created by spinning the wafer 78 causes substantially all of the semiconductor processing liquid to be removed from the upper surface of the wafer 78, thereby drying the wafer 78.

FIG. 6C illustrates the semiconductor wafer 78 after the spin clean process within the spin clean chamber 22. It should be noted that substantially all of the ash and metal particles 96 may have been removed from the hydrophilic surface of the oxide layer 94 on the wafer 78 by the spin clean process.

Referring again to FIG. 1, the robot 30 may then transport the semiconductor wafer 78 from the spin clean chamber 22 to the vertical immersion clean chamber 24.

Referring to FIG. 4A the robot arm 32 may place the wafer 78 onto the wafer gripper 54 of one of the vertical immersion clean apparatuses 26.

Referring now to FIG. 5C, the wafer 78 may then be placed into the liquid tank 62 within the main body 52 of the vertical immersion clean apparatus 26 by the wafer gripper 44 to remove the oxide layer 94 from and further clean the wafer 78. Although not illustrated in detail, it should be understood that the wafer gripper 44 may receive the wafer 78 from the robot arm 32 and further transport the wafer 78 into the main body 52 of the vertical immersion apparatus 26. As illustrated, the wafer 78 may be vertically immersed in the first tank liquid 64 in that the upper and lower surfaces of the wafer 78 may be substantially perpendicular to a surface 75 of the first tank liquid 64 or the central axis 97 of the wafer 78 may be substantially parallel to the surface 75 of the first tank liquid 64.

Referring to FIG. 5D, the wafer 78 may be completely immersed within the first tank liquid 64 in its vertical orientation thereby placing the wafer in an immersion position within the liquid tank 62. The first tank liquid 64 may be hydrofluoric acid or another semiconductor processing liquid suitable for removing the oxide layer 94.

FIG. 6D illustrates the wafer 78 after the wafer 78 has been immersed within the first tank liquid 64. It should be noted that the oxide layer 94 has been removed, and the exposed silicon of the wafer 78 may have a hydrophobic surface.

As illustrated in FIG. 5E, the first tank liquid 64 may then be drained from the liquid tank 62 through the drain 68 and either disposed of or recycled.

As illustrated in FIG. 5F, a second tank liquid 74, such as de-ionized water, or other semiconductor processing liquid, may then be pumped into the liquid tank 62 through the inlet 66 to rinse the wafer 78.

As illustrated in FIG. 5G, the second tank liquid 74 may be pumped to a depth similar to that of the first tank liquid such that the entire wafer 78 is immersed within the second tank liquid 74 while the wafer 78 is in the immersion position within the liquid tank 62.

As illustrated in FIG. 5H, the wafer 78, while still vertically oriented, may then be removed from the second tank liquid 74 and the liquid tank 62 by the wafer gripper 54. As the wafer 78 is removed from the second tank liquid 74, isopropyl alcohol (IPA) vapor 76, or other suitable vapor that reduces the surface tension of water when it is dissolved therein, may be directed from the vapor pipes 58 and the vapor nozzles to points on opposing sides (such as the upper and a lower surface) of the wafer 78 as the wafer 78 is pulled from the second tank liquid to dry the wafer 78. As illustrated, a meniscus 98 from the second tank liquid 74 forms on each side of the wafer 78 as the wafer 78 is pulled from the second tank liquid 74 where the upper and lower surfaces of the wafer 78 contact the surface 75 of the second tank liquid 74. The IPA vapor 76, on both sides of the wafer 78, is directed at an upper end of the meniscus 98. As the IPA vapor strikes the meniscus 98 and the wafer 78, the second tank liquid 74 is “pushed off” the hydrophobic surface of the wafer 78 back into the liquid tank 62 with the remainder of the second tank liquid 74. As a result, when the wafer 78 is pulled from the main body 52 of the vertical immersion clean apparatus 26, the wafer 78 is substantially complete dry.

Although not illustrated in detail, it should be understood that, similarly to FIG. 5C, the upper surface of the wafer 78 may be substantially perpendicular to the surface 75 of the second tank liquid 74 or the central axis 97 of the wafer 78 may be substantially parallel to the surface 75 of the second tank liquid 74 while the wafer 78 is being removed from the second tank liquid 74.

Referring again to FIG. 1, the wafer 78 may then be removed from the vertical immersion clean chamber 24 and transported by the robot 30 back to the wafer cassettes 14. The wafer 78 may then be transferred to another wafer processing apparatus.

As illustrated in FIG. 6E, source and drain regions 100 may then be deposited within the source and drain trenches 90 on the semiconductor wafer 78. It should be understood the processing step illustrated in FIG. 6E may take place in a separate semiconductor wafer processing apparatus than the one illustrated in FIG. 1.

It should be understood that the wafer 78 illustrated in FIGS. 6A-6E is intended only to be an example of one possible semiconductor substrate that could be processed with the embodiment of the invention described herein.

One advantage is that both the hydrophilic and the hydrophobic surfaces are able to be cleaned and dried using techniques that are most suitable for each. Therefore, a more effective wafer processing apparatus and method are provided.

Although only one semiconductor wafer 78 is described above as being processed by the semiconductor substrate processing apparatus 10, it should be understood that multiple wafers may be within the apparatus 10 simultaneously undergoing the various processing steps provided by the different processing chambers 16. For example, referring again to FIG. 1, after the robot 30 transports a first wafer from the plasma ash processing chamber 20 to one of the spin clean chambers 22, a second wafer may be transported from the cassettes 14 to the plasma ash chamber 20. Likewise, after the robot 30 transfers the first wafer from the spin clean chamber 22 to the vertical immersion clean chamber 24, the second wafer may be transported to the spin clean chamber 22, and a third wafer may be transported to the plasma ash processing chamber 20. In such a manner it is possible to process multiple wafers simultaneously thereby increasing wafer production.

Other embodiments of the invention may have additional, or different, processing chambers besides the plasma ash chamber such as additional spin clean chambers or vertical immersion clean chambers. The plasma ash chamber may utilize different plasma gases, such as hydrogen. The apparatus may not include the plasma ash processing chamber at all. The order in which the wafer is processed by the various chambers may be varied as well.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A method comprising:
dispensing a first semiconductor processing liquid onto a surface of a semiconductor substrate;
spinning the semiconductor substrate to remove the first semiconductor substrate from the surface of the semiconductor substrate; and
immersing the semiconductor substrate in a second semiconductor processing liquid.

2. The method of claim 1, further comprising removing the semiconductor substrate from the second semiconductor processing liquid and directing vapor at the surface of the semiconductor substrate where the surface of the semiconductor substrate contacts a surface of the second semiconductor processing fluid while the semiconductor substrate is being removed from the second semiconductor processing liquid.

3. The method of claim 2, wherein the surface of the substrate is hydrophilic during said dispensing and spinning of the substrate and the surface of the substrate is hydrophobic during said removal of the substrate from the second semiconductor processing liquid.

4. The method of claim 2, further comprising immersing the semiconductor substrate in a third semiconductor substrate processing liquid.

5. The method of claim 2, wherein the vapor is isopropyl alcohol vapor.

6. The method of claim 2, wherein the surface of the semiconductor substrate is substantially perpendicular to the surface of the second semiconductor processing liquid while the semiconductor substrate is immersed in and being removed from the second semiconductor processing fluid.

7. The method of claim 2, wherein the surface of the semiconductor substrate has a plurality of transistors formed thereon.

8. The method of claim 7, further comprising exposing the surface of the semiconductor substrate to plasma to remove a layer of photoresist formed over at least some of the transistors.

9. The method of claim 8, wherein said dispensing of the first semiconductor processing fluid onto the surface of the semiconductor substrate and said spinning of the semiconductor substrate removes substantially all of the photoresist residue from the surface of the semiconductor substrate and at least a portion of the surface of the semiconductor substrate is hydrophilic during said dispensing and spinning.

10. The method of claim 9, wherein at least a portion of the surface of the semiconductor substrate is hydrophobic during said immersion of the semiconductor substrate in the second semiconductor processing liquid.
